(19) United States
(12) Patent Application Publication
(10) Pub. No.: US 2026/0155562 A1
(43) Pub. Date: Jun. 4, 2026

(54) ANTENNA-EFFECT ELECTROSTATIC DISCHARGE DETECTION CIRCUIT AND METHOD FOR MEASURING ANTENNA-EFFECT ELECTROSTATIC DISCHARGING QUANTITY

(71) Applicant: MEDIATEK INC., Hsinchu City (TW)

(72) Inventors: Chun-Cheng HSU, Hsinchu City (TW); Yan-Liang JI, Hsinchu City (TW)

(21) Appl. No.: 19/401,544

(22) Filed: Nov. 26, 2025

Related U.S. Application Data
(60) Provisional application No. 63/726,676, filed on Dec. 2, 2024.

(51) Int. Cl. H01Q 1/50; G01R 29/12

(52) U.S. Cl. CPC H01Q 1/50; G01R 29/12

(57) ABSTRACT

An antenna-effect electrostatic discharge (ESD) detection circuit and a method for measuring the antenna-effect ESD quantity are provided. The antenna-effect ESD detection circuit includes a first antenna-effect ESD detection device and a first ESD protection device. The first antenna-effect ESD detection device is coupled between a first pad and a second pad. The first ESD protection device is coupled between an I/O pad and the first pad. The internal circuit is coupled to the I/O pad, the first external ESD protection device, and the first antenna-effect ESD detection device.

### CROSS REFERENCE TO RELATED APPLICATIONS

This application claims the benefit of U.S. provisional application No. 63/726,676, filed December 2, 2024, the entirety of which is incorporated by reference herein.

### TECHNICAL FIELD

The present disclosure relates to a semiconductor device and a method for fabricating a semiconductor device, and, in particular, it relates to an antenna-effect electrostatic discharge (ESD) detection circuit and a method for measuring the antenna-effect ESD quantity.

### BACKGROUND

During plasma processing in semiconductor device fabrication, charges accumulated on conductive interconnects (acting as antennas) can generate high voltage stress across thin gate oxides, leading to tunneling currents and potential dielectric breakdown. This phenomenon is known as the “antenna-effect” or “plasma induced charging”. The antenna effect is typically assessed using gate leakage current in test structures, which results from cumulative charge-induced degradation of the gate oxide. However, this method cannot quantify the total charging stress after dielectric breakdown has occurred.

Thus, a novel test structure is needed to directly monitor the charging stress induced by the antenna effect.

### BRIEF SUMMARY

An embodiment of the present disclosure provides an antenna-effect electrostatic discharge (ESD) detection circuit. The antenna-effect ESD detection circuit includes a first antenna-effect ESD detection device and a first external electrostatic discharge (ESD) protection device. The first antenna-effect ESD detection device is coupled between a first pad and a second pad. The first ESD protection device is coupled between an input/output (I/O) pad and the first pad. The internal circuit is coupled to the I/O pad, the first external ESD protection device, and the first antenna-effect ESD detection device.

An embodiment of the present disclosure provides a method for measuring the antenna-effect ESD quantity. The method includes fabricating a chip surrounded by a scribe line on a semiconductor wafer. The chip includes an antenna-effect electrostatic discharge (ESD) detection circuit for an internal circuit. The antenna-effect ESD detection circuit includes an antenna-effect ESD detection device and an external electrostatic discharge (ESD) protection device. The antenna-effect ESD detection device is coupled between a first pad and a second pad. The external electrostatic discharge (ESD) protection device is coupled between an input/output (I/O) pad and the first pad. The internal circuit is coupled to the I/O pad, the external ESD protection device, and the antenna-effect ESD detection device. A drain of the antenna-effect ESD detection device is connected to an antenna structure. The method further includes obtaining a first threshold voltage of the antenna-effect ESD detection device of the chip. The method further includes removing charges trapped in a floating gate of the antenna-effect ESD detection device.

### BRIEF DESCRIPTION OF THE DRAWINGS

The present disclosure can be more fully understood by reading the subsequent detailed description and examples with references made to the accompanying drawings, wherein:

FIG. 1 is a schematic connection diagram of an antenna-effect electrostatic discharge (ESD) detection circuit in accordance with some embodiments of the disclosure;

FIG. 2 is a schematic connection diagram of an antenna-effect electrostatic discharge (ESD) detection circuit in accordance with some embodiments of the disclosure;

FIG. 3A is a schematic top view of a ESD detection device in accordance with some embodiments of the disclosure;

FIG. 3B is a schematic cross-sectional view of the ESD detection device taken along the line A-A’ of FIG. 3A in accordance with some embodiments of the disclosure;

FIG. 4A is a schematic top view of a ESD detection device in accordance with some embodiments of the disclosure;

FIG. 4B is a schematic cross-sectional view of the ESD detection device taken along the line A-A’ of FIG. 4A in accordance with some embodiments of the disclosure;

FIG. 5 is a flow chart of a method for measuring the antenna-effect ESD quantity in accordance with some embodiments of the disclosure;

FIG. 6 is a schematic top view of a semiconductor wafer, showing the arrangement of the ESD detection devices;

FIG. 7 is a schematic top view of a package including a chip divided from the semiconductor wafer of FIG. 6;

FIG. 8 is a schematic top view of a package including the chip of FIG. 7; and

FIG. 9 is a schematic top view of a final product including the package of FIG. 8.

### DETAILED DESCRIPTION

The following description is made for the purpose of illustrating the general principles of the disclosure and should not be taken in a limiting sense. The scope of the disclosure is best determined by reference to the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

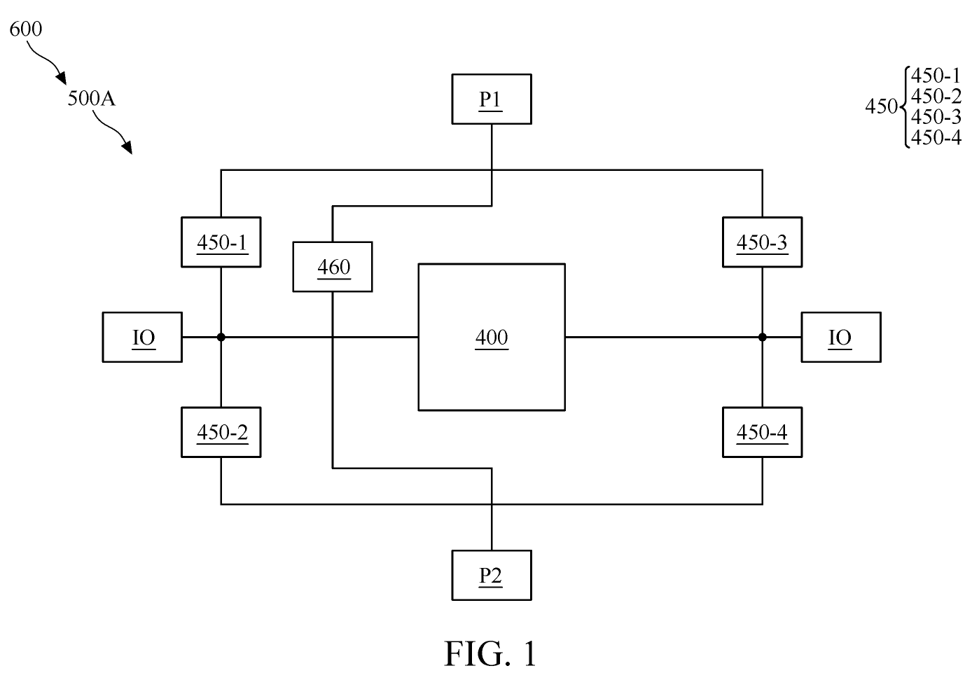

FIG. 1 is a schematic connection diagram of an antenna-effect electrostatic discharge (ESD) detection circuit 500A disposed in a system 600 in accordance with some embodiments of the disclosure. The system 600 includes the antenna-effect electrostatic discharge (ESD) detection circuit 500A. The antenna-effect ESD detection circuit 500A includes an internal circuit 400, external electrostatic discharge (ESD) protection devices 450 (including external ESD protection devices 450-1, 450-2, 450-3 and 450-4) and an antenna-effect ESD detection device 460 (including antenna-effect ESD detection devices 460A and 460B shown in the following figures). The internal circuit 400 is coupled (electrically connected) to input/output pads IO, a first pad P1 and a second pad P2 of the system 600. In some embodiments, when the internal circuit 400 is in operation, the first pad P1 receives a power supply voltage (VDD), and the second pad P2 is coupled to ground (VSS).

The external ESD protection devices 450 are used to prevent an external electrostatic discharge current from flowing through the internal circuit 400. In some embodiments, the antenna-effect electrostatic discharge (ESD) detection circuit 500A may include four external ESD protection devices 450-1, 450-2, 450-3 and 450-4. The external ESD protection devices 450-1, 450-2, 450-3 and 450-4 may be identical to each other. The external ESD protection devices 450-1 and 450-3 may be coupled (electrically connected) between the input/output pad IO and the first pad P1 of the antenna-effect ESD detection circuit 500A to prevent an external electrostatic discharge current from flowing through the internal circuit 400. In addition, the external ESD protection devices 450-2 and 450-4 may be coupled (electrically connected) between the input/output pad IO and the second pad P2 of the antenna-effect ESD detection circuit 500A to prevent an external electrostatic discharge current from flowing through the internal circuit 400.

In some embodiments, the external ESD protection devices 450-1 and 450-3 are connected in parallel and also coupled (electrically connected) between the first pad P1 and the internal circuit 400. In addition, the external ESD protection devices 450-2 and 450-4 are connected in parallel and also coupled (electrically connected) between the second pad P2 and the internal circuit 400. The connections of external ESD protection devices 450-1, 450-2, 450-3 and 450-4 can prevent an external electrostatic discharge current from flowing through the internal circuit 400.

In some embodiments, when the external ESD protection devices 450-1, 450-2, 450-3 and 450-4 are composed of diodes. The cathode of each of the external ESD protection devices 450-1 and 450-3 is coupled to the first pad P1. The anode of each of the external ESD protection devices 450-2 and 450-4 is coupled to the second pad P2. The anode of each of the external ESD protection devices 450-1 and 450-3 and the cathode of each of the external ESD protection devices 450-2 and 450-4 are coupled to the input/output pads IO. In addition, the anode the external ESD protection device 450-1 is coupled to the cathode of the external ESD protection device 450-2. The anode the external ESD protection device 450-3 is coupled to the cathode of the external ESD protection device 450-4.

The antenna-effect ESD detection device 460 has a single non-volatile memory device structure and is used to detect the antenna-effect ESD quantity during any plasma processes in the fabrication process. As shown in FIG. 1, the antenna-effect ESD detection device 460 may be coupled between the first pad P1 and the second pad P2. In some embodiments, the antenna-effect ESD detection device 460 is in parallel connection with the series connected external ESD protection devices 450-1 and 450-2 coupled between the first pad P1 and the second pad P2. In addition, the antenna-effect ESD detection device 460 is in parallel connection with the series connected external ESD protection devices 450-3 and 450-4 coupled between the first pad P1 and the second pad P2.

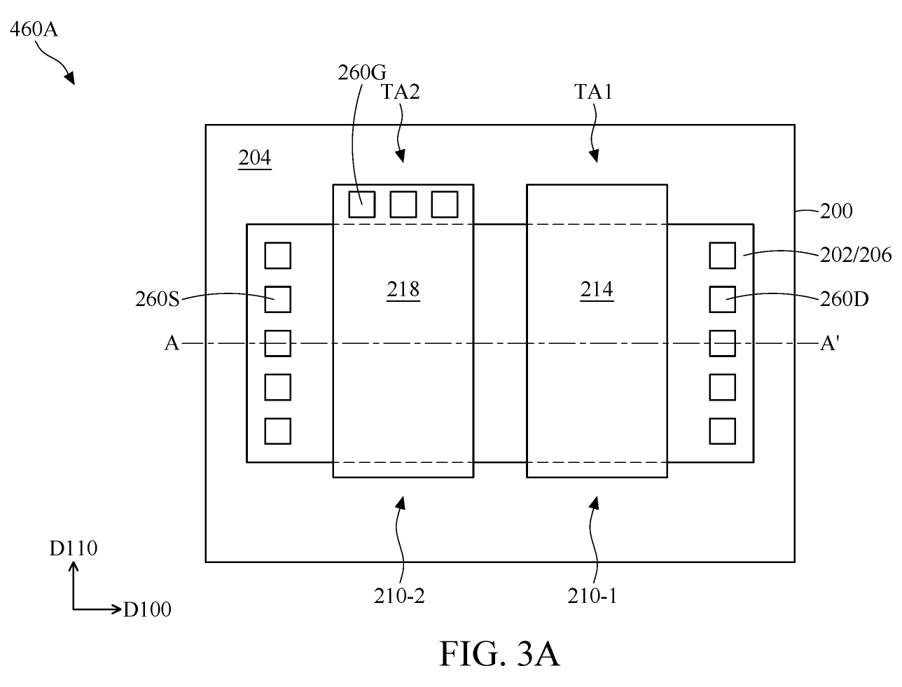

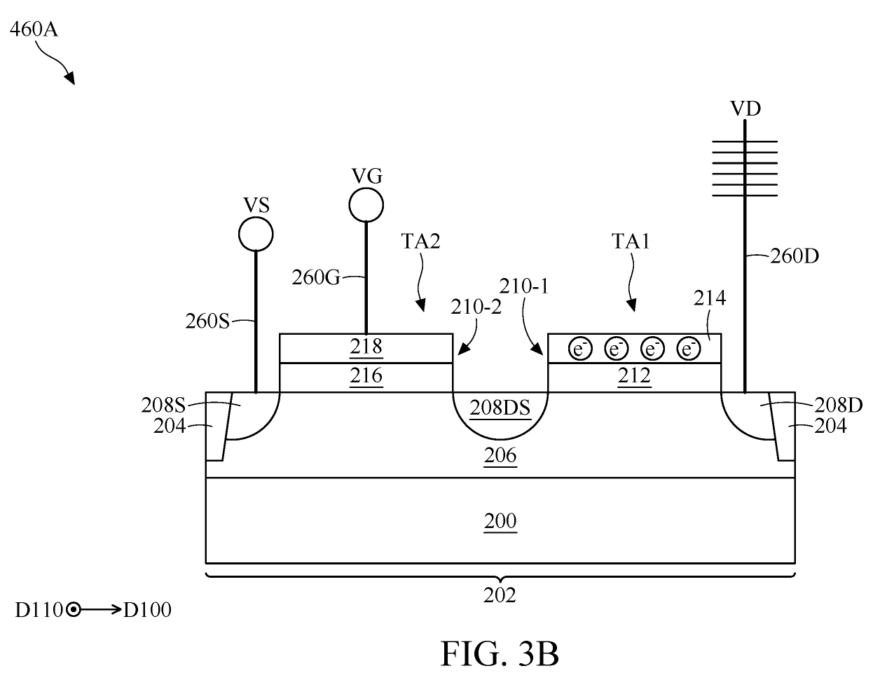

In some embodiments, when the antenna-effect ESD detection device 460 of the antenna-effect electrostatic discharge (ESD) detection circuit 500A is subjected to a plasma process, a floating gate (will be described using FIGS. 3A, 3B, 4A, and 4B) of the antenna-effect ESD detection device 460 may be used to capture the charge induced by the antenna effect during wafer processing. This captured charge affects the device turn-on voltage and allows for an assessment of the antenna-effect ESD quantity by observing the shift in the threshold voltage of the antenna-effect ESD detection device 460. The antenna-effect ESD may be applied to trim/calibrate the operation voltage/current of the internal circuit 400.

In some embodiments, the antenna-effect ESD detection device 460 includes a single non-volatile memory device, such as a single one-time programmable (OTP) memory detection device or a single flash memory device.

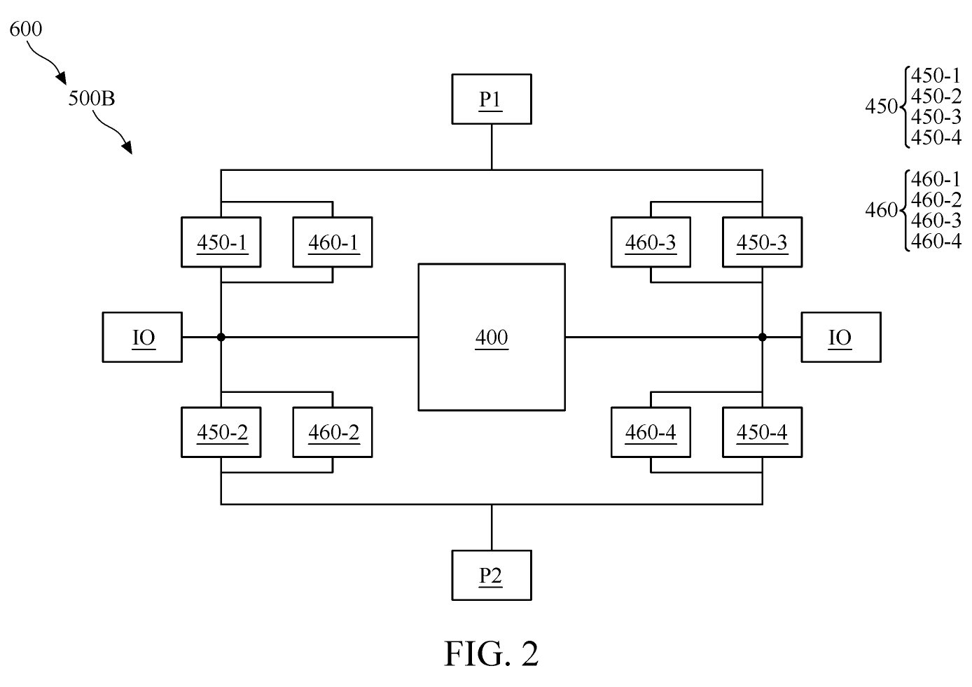

FIG. 2 is a schematic connection diagram of an antenna effect electrostatic discharge (ESD) detection circuit 500B disposed in a system 600 in accordance with some embodiments of the disclosure. Elements of the embodiments that are the same or similar to those previously described with reference to FIG. 1 are not repeated herein, in the interests of brevity.

As shown in FIG. 2. the system 600 includes the antenna effect electrostatic discharge (ESD) detection circuit 500B. The antenna effect ESD detection circuit 500B includes an internal circuit 400, external electrostatic discharge (ESD) protection devices 450 (including external ESD protection devices 450-1, 450-2, 450-3 and 450-4) and antenna-effect ESD detection devices 460 (including antenna-effect ESD detection devices 460-1, 460-2, 460-3 and 460-4). The internal circuit 400 is coupled (electrically connected) to an input/output pad IO, a first pad P1 and a second pad P2 of the system 600. In some embodiments, when the internal circuit 400 is in operation, the first pad P1 receives a power supply voltage (VDD), and the second pad P2 is coupled to ground (VSS).

In some embodiments, the antenna effect electrostatic discharge (ESD) detection circuit 500B may include four antenna-effect ESD detection devices 460-1, 460-2, 460-3 and 460-4. The antenna-effect ESD detection devices 460-1, 460-2, 460-3 and 460-4 may be identical to each other. Each of the antenna-effect ESD detection devices 460-1, 460-2, 460-3 and 460-4 has a single non-volatile memory device structure and is used to detect the antenna-effect ESD quantity during the plasma processes of the fabrication process. For example, the antenna-effect ESD detection devices 460-1 and 460-3 may be coupled (electrically connected) between the input/output pad IO and the first pad P1 of the antenna effect ESD detection circuit 500B. In addition, the antenna-effect ESD detection devices 460-2 and 460-4 may be coupled (electrically connected) between the input/output pad IO and the second pad P2 of the antenna effect ESD detection circuit 500B.

In some embodiments, the antenna-effect ESD detection devices 460-1 and 460-3 are also coupled (electrically connected) between the first pad P1 and the internal circuit 400. In addition, the antenna-effect ESD detection devices 460-2 and 460-4 are also coupled (electrically connected) between the second pad P2 and the internal circuit 400. The connections of antenna-effect ESD detection devices 460-1, 460-2, 460-3 and 460-4 can detect the antenna-effect ESD quantity during any plasma processes in the fabrication process.

In some embodiments, the antenna-effect ESD detection device 460-1 and the external ESD protection device 450-1 are connected in parallel. The antenna-effect ESD detection device 460-2 and the external ESD protection device 450-2 are connected in parallel. The antenna-effect ESD detection device 460-3 and the external ESD protection device 450-3 are connected in parallel. The antenna-effect ESD detection device 460-4 and the external ESD protection device 450-4 are connected in parallel.

As shown in FIG. 2, the parallel connected antenna-effect ESD detection device 460-1 and external ESD protection device 450-1 is in series connection with the parallel connected antenna-effect ESD detection device 460-2 and external ESD protection device 450-2. In addition, the parallel connected antenna-effect ESD detection device 460-3 and external ESD protection device 450-3 is in series connection with the parallel connected antenna-effect ESD detection device 460-4 and external ESD protection device 450-4.

In some embodiments, when the antenna-effect ESD detection device 460 of the antenna effect electrostatic discharge (ESD) detection circuit 500B is subjected to a plasma process, a floating gate (will be described using FIGS. 3A, 3B, 4A, and 4B) of the antenna-effect ESD detection device 460 may be used to capture the charge induced by the antenna effect during wafer processing before the external ESD protection device 450 fails due to a short-circuit. This captured charge affects the device turn-on voltage and allows for an assessment of the antenna-effect ESD quantity by observing the shift in the threshold voltage of the antenna-effect ESD detection device 460. The antenna-effect ESD may be applied to trim/calibrate the operation voltage/current of the internal circuit 400.

In some embodiments, each of the antenna-effect ESD detection devices 460-1, 460-2, 460-3 and 460-4 includes a single non-volatile memory device, such as a single one-time programmable (OTP) memory detection device or a single flash memory device.

FIG. 3A is a schematic top view of an antenna-effect ESD detection device 460A in accordance with some embodiments of the disclosure. FIG. 3B is a schematic cross-sectional view of the antenna-effect ESD detection device 460A taken along the line A-A’ of FIG. 3A in accordance with some embodiments of the disclosure. For illustration, a conductive routing 260G coupled to a gate electrode 218 of the antenna-effect ESD detection device 460A is also shown in the FIG. 3B.

In some embodiments as shown in FIG. 3A, the antenna-effect ESD detection device 460A is a one-time programmable (OTP) memory device. In some embodiments, the antenna-effect ESD detection device 460A includes a substrate 200, a floating gate transistor TA1 and a select transistor TA2 and conductive routings 260G, 260D, and 260S.

As shown in FIG. 3A, the substrate 200 has an active region 202 surrounded by isolation features 204. In some embodiments, the substrate 200 includes a semiconductor wafer or a silicon on insulator (SOI) wafer. The substrate 200 may be doped with dopants of p-type or n-type according to a predetermined design rule.

The antenna-effect ESD detection device 460A may further include a well region 206 formed within the active region 202 in the substrate 200. In some embodiments, the well region 206 may be doped with dopants having a first conductivity type. In some embodiments in which the antenna-effect ESD detection device 460A includes a P-type oxide-semiconductor field effect-based (PMOS-based) OTP memory device, the well region 206 is, for example, an N-type well region. In some embodiments in which the antenna-effect ESD detection device 460A includes an N-type oxide-semiconductor field effect-based (NMOS-based) OTP memory device, the well region 206 is, for example, a P-type well region.

The floating gate transistor TA1 and the select transistor TA2 are disposed on the well region 206. The floating gate transistor TA1 and the select transistor TA2 connected in series are disposed in the same active region 202. As shown in FIG. 3A, the floating gate transistor TA1 and the select transistor TA2 may form a unit cell.

In some embodiments as shown in FIG. 3A, the floating gate transistor TA1 is disposed on the well region 206 and includes a gate structure 210-1, a source/drain doped region 208DS and a source/drain doped region 208D. The gate structure 210-1 is disposed within the active region 202 on the substrate 200 and extends in the direction D110. The direction D110 may serve as an extending direction of the gate structure 210-1 (also called a floating gate structure 210-1). In some embodiments, the gate structure 210-1 includes a gate insulating layer 212 and a gate electrode 214 (also called a floating gate 214). The gate insulating layer 212 is formed on the substrate 200. The gate electrode 214 is formed on the gate insulating layer. In addition, gate spacers (not shown) are formed on the opposite sides of the gate electrode 214.

The source/drain doped region 208DS and the source/drain doped region 208D are located within the same active region 202 in the substrate 200. The source/drain doped region 208DS and the source/drain doped region 208D are disposed on the well region 206 and on opposite sides of the gate structure 210-1 of the floating gate transistor TA1 along the direction D100. In some embodiments, source/drain doped region 208DS and the source/drain doped region 208D may be doped with dopants having a second conductivity type opposite to the first conductivity type. For example, when the well region 206 is N-type, the source/drain doped region 208DS and the source/drain doped region 208D are P-type. When the well region 206 is P-type, the source/drain doped region 208DS and the source/drain doped region 208D are N-type.

The select transistor TA2 is disposed on the well region 206 and includes a gate structure 210-2 (also called a select gate structure 210-2), a source/drain doped region 208S and the source/drain doped region 208DS. The gate structure 210-2 is disposed within the active region 202 of the substrate 200. In addition, the gate structure 210-2 is located beside the first gate structure 210-1 of the floating gate transistor TA1 along the direction D100. The gate structure 210-2 is disposed within the active region 202 on the substrate 200 and extends in the direction D110. The direction D110 may also serve as an extending direction of the gate structure 210-2. In some embodiments, the gate structure 210-2 includes a gate insulating layer 216 and a gate electrode 218 (also called a select gate 218). The gate insulating layer 216 is formed on the substrate 200 and separated from the gate insulating layer 212 of the floating gate transistor TA1. The gate electrode 218 is formed on the gate insulating layer 216 and separated from the gate electrode 214 of the floating gate transistor TA1. In addition, gate spacers (not shown) are formed on the opposite sides of the gate electrode 218.

The source/drain doped region 208S and the source/drain doped region 208DS are located within the same active region 202 in the substrate 200. The source/drain doped region 208S and the source/drain doped region 208DS are disposed on the well region 206 and on opposite sides of the gate structure 210-2 of the select transistor TA2 along the direction D100. In addition, the source/drain doped region 208DS of the floating gate transistor TA1 is commonly used as the source/drain doped region of the select transistor TA2 opposite the source/drain doped region 208S. In some embodiments, the source/drain doped region 208S may be doped with dopants having the second conductivity type opposite to the first conductivity type. For example, when the well region 206 is N-type, the source/drain doped region 208S is P-type. When the well region 206 is P-type, the source/drain doped region 208S is N-type.

The conductive routings 260G, 260D, and 260S are formed over the substrate 200. In addition, the conductive routings 260G, 260D, and 260S are configured to be electrically connected to various terminals of the antenna-effect ESD detection device 460A. For example, the conductive routing 260G is coupled to the gate (i.e., the gate structure 210-2 of the select transistor TA2) of the antenna-effect ESD detection device 460A. The conductive routing 260D is coupled to the drain (i.e., the source/drain doped region 208D) of the antenna-effect ESD detection device 460A. The conductive routing 260S is coupled to the source (i.e., the source/drain doped region 208S) of the antenna-effect ESD detection device 460A.

In some embodiments, the gate structure 210-1 of the floating gate transistor TA1 is not coupled to any conductive routings. In some embodiments, the gate structure 210-1 of the floating gate transistor TA1 is electrically floating.

In some embodiments, the conductive routings 260G, 260D and 260S at least include a bottom interconnection-level conductive trace (e.g., 1st interconnection-level conductive trace (M1)) and a bottom conductive via (not shown) coupled to the bottom interconnection-level conductive trace. In some embodiments, the conductive routings 260G, 260D and 260S may further include upper interconnection-level conductive traces (e.g., 2nd interconnection-level conductive trace (M2) to the top interconnection-level conductive trace (Mtop)) located above the bottom interconnection-level conductive trace and upper conductive vias (not shown) coupled to the upper interconnection-level conductive traces.

In some embodiments, the conductive routing 260D having any combination of the bottom interconnection-level conductive trace, the bottom conductive via, the upper interconnection-level conductive traces and upper conductive vias is electrically floating during the fabrication processes of the antenna-effect ESD detection device 460A. At this time, the conductive routing 260D may act as an antenna structure of the antenna-effect ESD detection device 460A. A floating gate structure (e.g., the gate structure 210-1 of the floating gate transistor TA1) is used to capture the charge induced by the antenna effect during wafer processing. This captured charge affects the device turn-on voltage and allows for an assessment of the charging quantity by observing the shift in the device threshold voltage.

In some embodiments, when the antenna-effect ESD detection device 460A is applied as the antenna-effect ESD detection device 460 of the antenna effect electrostatic discharge (ESD) detection circuit 500A of FIG. 1, the drain (i.e., the source/drain doped region 208D) of the antenna-effect ESD detection device 460A is coupled to the first pad P1. The source (i.e., the source/drain doped region 208S) of the antenna-effect ESD detection device 460A is coupled to the second pad P2.

In some embodiments, when the antenna-effect ESD detection device 460A is applied as the antenna-effect ESD detection devices 460-1 and 460-3 of the antenna effect electrostatic discharge (ESD) detection circuit 500B of FIG. 2, the drain (i.e., the source/drain doped region 208D) of the antenna-effect ESD detection device 460A is coupled to the first pad P1. In addition, the source (i.e., the source/drain doped region 208S) of the antenna-effect ESD detection device 460A is coupled to the second pad P2 through the antenna-effect ESD detection devices 460-2 and 460-4. When the antenna-effect ESD detection device 460A is applied as the antenna-effect ESD detection devices 460-2 and 460-4 of the antenna effect electrostatic discharge (ESD) detection circuit 500B of FIG. 2, the drain (i.e., the source/drain doped region 208D) of the antenna-effect ESD detection device 460A is coupled to the first pad P1 through the antenna-effect ESD detection devices 460-1 and 460-3. In addition, the source (i.e., the source/drain doped region 208S) of the antenna-effect ESD detection device 460A is coupled to the second pad P2.

When the antenna-effect ESD detection device 460A is subjected a plasma process, the charges induced by the antenna effect during wafer processing may be collected by the antenna structure (the conductive routing 260D), through the gate insulating layer 212 and trapped in the gate electrode 214 (the floating gate). The floating gate 214 of the antenna-effect ESD detection device 460A may be used to capture the charge induced by the antenna effect during wafer processing. This captured charge affects the device turn-on voltage and allows an the assessment of the antenna-effect ESD quantity by observing the shift in the threshold voltage of the antenna-effect ESD detection device 460A. In some embodiments, the threshold voltage of the antenna-effect ESD detection device 460A is measured by applying voltages to the gate electrode 218 (VG), the source/drain doped region 208D (VD), and the source/drain doped region 208S (VS) and observing the drain current. In some embodiments, the thickness of the gate insulating layer 212 can be adjusted to filter the induced charges having a lower energy, so that the antenna-effect ESD detection device 460A may monitor the induced charges having a specific energy range.

FIG. 4A is a schematic top view of an antenna-effect ESD detection device 460B in accordance with some embodiments of the disclosure. FIG. 4B is a schematic cross-sectional view of the antenna-effect ESD detection device 460B taken along the line A-A’ of FIG. 4A in accordance with some embodiments of the disclosure. For illustration, a conductive routing 360G coupled to a control gate 318 of the antenna-effect ESD detection device 460B is also shown in the FIG. 4B.

In some embodiments as shown in FIG. 4A, the antenna-effect ESD detection device 460B is a flash memory device. In some embodiments, the antenna-effect ESD detection device 460B includes a substrate 200, a gate structure 310, a source/drain doped region 308S, the source/drain doped region 308D and conductive routings 360G, 360D, and 360S.

As shown in FIG. 4A, the substrate 200 has an active region 302 surrounded by isolation features 204.

The antenna-effect ESD detection device 460B may further include a well region 306 formed within the active region 302 in the substrate 200. In some embodiments, the well region 306 may be doped with dopants having a first conductivity type. In some embodiments in which the antenna-effect ESD detection device 460B includes a P-channel flash memory device, the well region 306 is, for example, an N-type well region. In some embodiments in which the antenna-effect ESD detection device 460B includes an N-channel flash memory device, the well region 306 is, for example, a P-type well region.

The gate structure 310 is disposed on the well region 306 and includes a tunneling dielectric layer 312, a floating gate 314, a gate dielectric layer 316, the control gate 318 and conductive routings 360G, 360D, and 360S.

The tunneling dielectric layer 312 is disposed within the active region 302 of the substrate 200. In some embodiments, the tunneling dielectric layer 312 is formed of silicon oxide. In some embodiments, the tunneling dielectric layer 312 is formed by a growing process including thermal oxidation or a deposition process including chemical vapor deposition (CVD).

The floating gate 314 is disposed on the tunneling dielectric layer 312. In some embodiments, the floating gate 314 is formed of polysilicon. In some embodiments, the floating gate 314 is formed by a deposition process including chemical vapor deposition (CVD).

The gate dielectric layer 316 is disposed on the floating gate 314. In some embodiments, the gate dielectric layer 316 includes a single-layer structure including silicon oxide, silicon nitride, and silicon oxynitride, or a triple-layer structure including silicon oxide/silicon nitride/silicon oxide (ONO). In some embodiments, the gate dielectric layer 316 is formed by a deposition process including chemical vapor deposition (CVD) and atomic layer deposition (ALD).

The control gate 318 is disposed on the gate dielectric layer 316 and separated from the floating gate 314. In some embodiments, the control gate 318 is formed of polysilicon or conductive material. In some embodiments, the control gate 318 is formed by a deposition process including chemical vapor deposition (CVD).

The source/drain doped region 308S and the source/drain doped region 308D are located within the same active region 302 in the substrate 300. The source/drain doped region 308S and the source/drain doped region 308D are disposed on the well region 306 and on opposite sides of the gate structure 310 along the direction D100. In some embodiments, source/drain doped region 308S and the source/drain doped region 308D may be doped with dopants having a second conductivity type opposite to the first conductivity type. For example, when the well region 306 is N-type, the source/drain doped region 308S and the source/drain doped region 308D are P-type. When the well region 306 is P-type, the source/drain doped region 308S and the source/drain doped region 308D are N-type.

The conductive routings 360G, 360D, and 360S are formed over the substrate 200. In addition, the conductive routings 360G, 360D, and 360S are configured to be electrically connected to various terminals of the antenna-effect ESD detection device 460B. For example, the conductive routing 360G is coupled to the gate (i.e., the gate structure 310) of the antenna-effect ESD detection device 460B. The conductive routing 360D is coupled to the drain (i.e., the source/drain doped region 308D) of the antenna-effect ESD detection device 460B. The conductive routing 360S is coupled to the source (i.e., the source/drain doped region 308S) of the antenna-effect ESD detection device 460B.

In some embodiments, the conductive routings 360G, 360D and 360S at least include a bottom interconnection-level conductive trace (e.g., 1st interconnection-level conductive trace (M1)) and a bottom conductive via (not shown) coupled to the bottom interconnection-level conductive trace. In some embodiments, the conductive routings 360G, 360D and 360S may further include upper interconnection-level conductive traces (e.g., 2nd interconnection-level conductive trace (M2) to the top interconnection-level conductive trace (Mtop)) located above the bottom interconnection-level conductive trace and upper conductive vias (not shown) coupled to the upper interconnection-level conductive traces.

In some embodiments, the conductive routing 360D having any combination of the bottom interconnection-level conductive trace, the bottom conductive via, the upper interconnection-level conductive traces and upper conductive vias is electrically floating during the fabrication processes of the antenna-effect ESD detection device 460B. At this time, the conductive routing 360D may act as an antenna structure of the antenna-effect ESD detection device 460B. The floating gate 314 is used to capture the charge induced by the antenna effect during wafer processing. This captured charge affects the device turn-on voltage and allows for an assessment of the charging quantity by observing the shift in the device threshold voltage.

In some embodiments, when the antenna-effect ESD detection device 460B is applied as the antenna-effect ESD detection device 460 of the antenna effect electrostatic discharge (ESD) detection circuit 500A of FIG. 1, the drain (i.e., the source/drain doped region 308D) of the antenna-effect ESD detection device 460B is coupled to the first pad P1. The source (i.e., the source/drain doped region 308S) of the antenna-effect ESD detection device 460B is coupled to the second pad P2.

In some embodiments, when the antenna-effect ESD detection device 460B is applied as the antenna-effect ESD detection devices 460-1 and 460-3 of the antenna effect electrostatic discharge (ESD) detection circuit 500B of FIG. 2, the drain (i.e., the source/drain doped region 308D) of the antenna-effect ESD detection device 460B is coupled to the first pad P1. In addition, the source (i.e., the source/drain doped region 308S) of the antenna-effect ESD detection device 460B is coupled to the second pad P2 through the antenna-effect ESD detection devices 460-2 and 460-4. When the antenna-effect ESD detection device 460B is applied as the antenna-effect ESD detection devices 460-2 and 460-4 of the antenna effect electrostatic discharge (ESD) detection circuit 500B of FIG. 2, the drain (i.e., the source/drain doped region 308D) of the antenna-effect ESD detection device 460B is coupled to the first pad P1 through the antenna-effect ESD detection devices 460-1 and 460-3. In addition, the source (i.e., the source/drain doped region 308S) of the antenna-effect ESD detection device 460B is coupled to the second pad P2.

When the antenna-effect ESD detection device 460B is subjected to a plasma process, the charges induced by the antenna effect during wafer processing may be collected by the antenna structure (the conductive routing 360D), through the tunneling dielectric layer 312 and trapped in the floating gate 314. The floating gate 314 of the antenna-effect ESD detection device 460B may be used to capture the charge induced by the antenna effect during wafer processing. This charge affects the device turn-on voltage and allows for an assessment of the antenna-effect ESD quantity by observing the shift in the threshold voltage of the antenna-effect ESD detection device 460B. In some embodiments, the threshold voltage of the antenna-effect ESD detection device 460B is measured by applying voltages to the gate electrode 318 (VG), the source/drain doped region 308D (VD), and the source/drain doped region 308S (VS) and observing the drain current. In some embodiments, the thickness of the gate insulating layer 212 can be adjusted to filter the induced charges having a lower energy, so that the antenna-effect ESD detection device 460A may monitor the induced charges having a specific energy range.

Please refer to FIGS. 1, 2, 3A, 3B, 4A and 4B. When an antenna effect electrostatic discharge event occurs at the first pad P1, for example, the threshold voltage of the antenna-effect ESD detection device 460 (or any of the antenna-effect ESD detection devices 460-1 to 460-4) composed of the antenna-effect ESD detection device 460A or 460B is higher than the initial threshold voltage of the antenna-effect ESD detection device 460 measured before the antenna effect electrostatic discharge (ESD) event occurs.

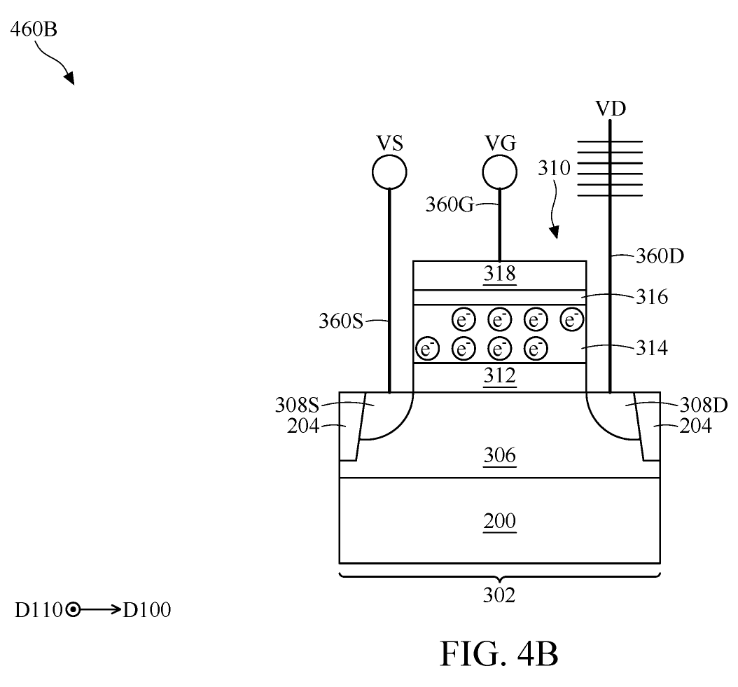

FIG. 6 is a schematic top view of a semiconductor wafer 100, showing the arrangements of the antenna-effect ESD detection devices 460. As shown in FIG. 6, the semiconductor wafer 100 has the substrate 200 having scribe lines 102 and chips 104. The adjacent chips 104 are separated by the scribe lines 102. In addition, the scribe lines 102 surrounding the chips 104 may provide spaces for the singulation process (including sawing, laser grooving or other applicable singulation processes) to cut the semiconductor wafer 100 into individual chips 104 without damaging the semiconductor dies. In some embodiment, the scribe lines 102 are also provided spaces for one or more test devices 160 disposed therein without occupying the space for the chips 104. In addition, the test devices 160 may be removed after the semiconductor wafer 100 is subjected the singulation process.

In some embodiments, the system 600 is fabricated in chips 104 of the semiconductor wafer 100 as shown in FIG. 6. In addition, the test devices 160 fabricated in the scribe lines 102 may include the antenna-effect ESD quantity detection devices having a physical characteristic (e.g., size, structure) the same as (or similar to) the antenna-effect ESD detection device 460 fabricated in one of the chips 104. In addition, the test device 160 and the antenna-effect ESD detection device 460 in one of the chips 104 may be formed using the same fabrication processes. It is noted that the type of the test device 160 is not limited to the disclosed embodiment. For example, the test device 160 may include active devices, passive devices, functional circuits or other applicable devices that are similar to those fabricated in the chips 104. For example, the test device 160 may include geometric structures similar to various features of the semiconductor devices (e.g., various doped regions, various material layers) in the chips 104 for the testing of various physical characteristic variables, such as strain, doping type or concentration, the critical dimension of the devices (such as channel length, channel width, gate oxide thickness), electrical performances (such as threshold voltage, saturation current or leakage current), or other useful characteristics. The test devices 160 are deposed in the scribe lines 102 for testing to ensure that processing of subsequent device elements does not cause the resulting product to fail.

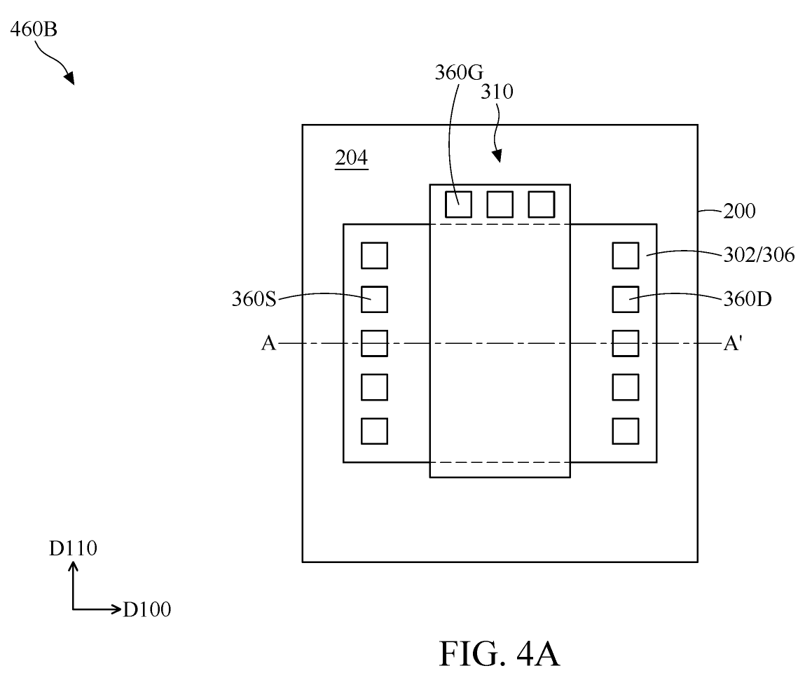

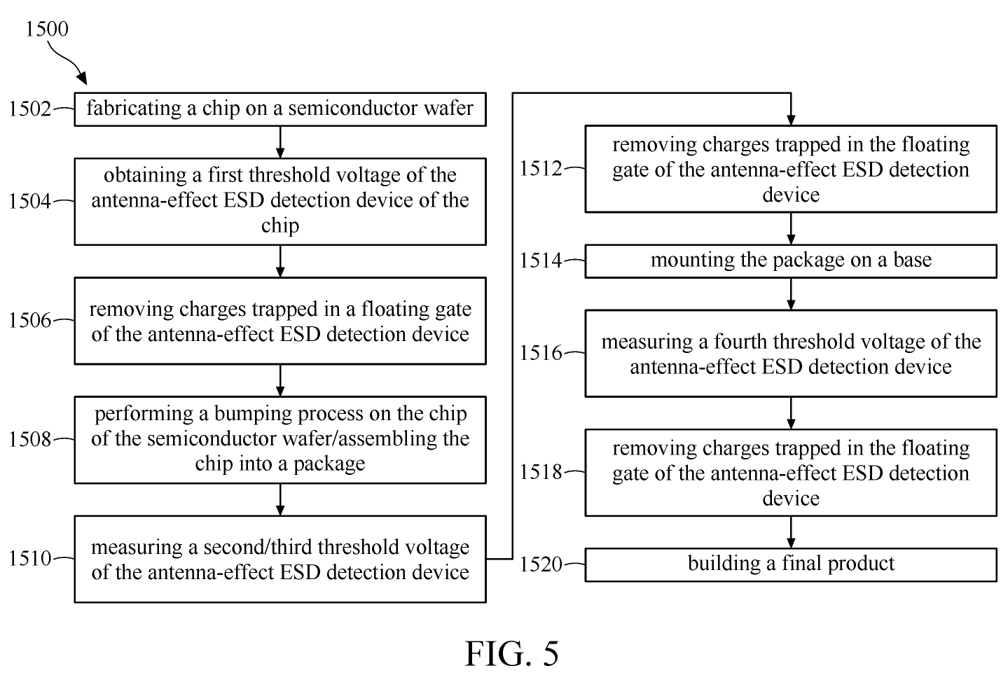

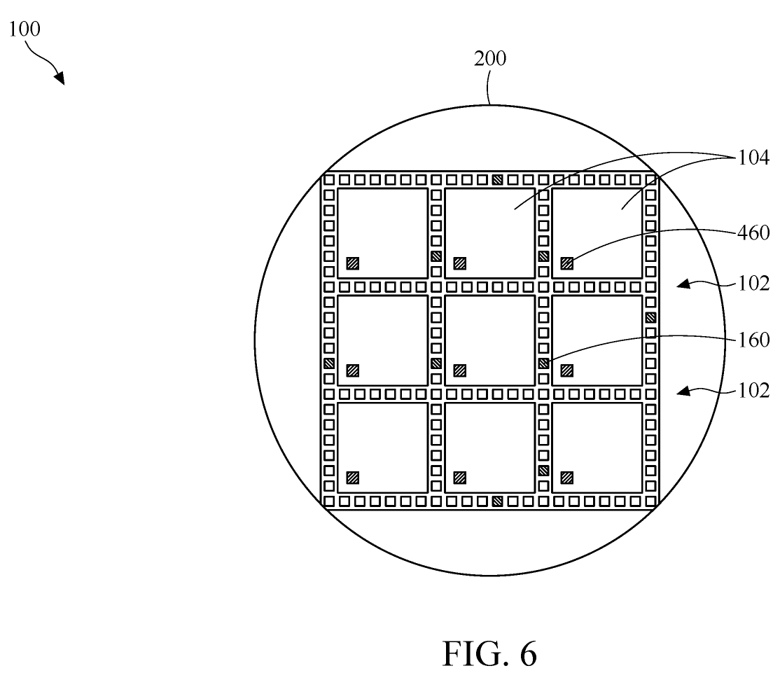

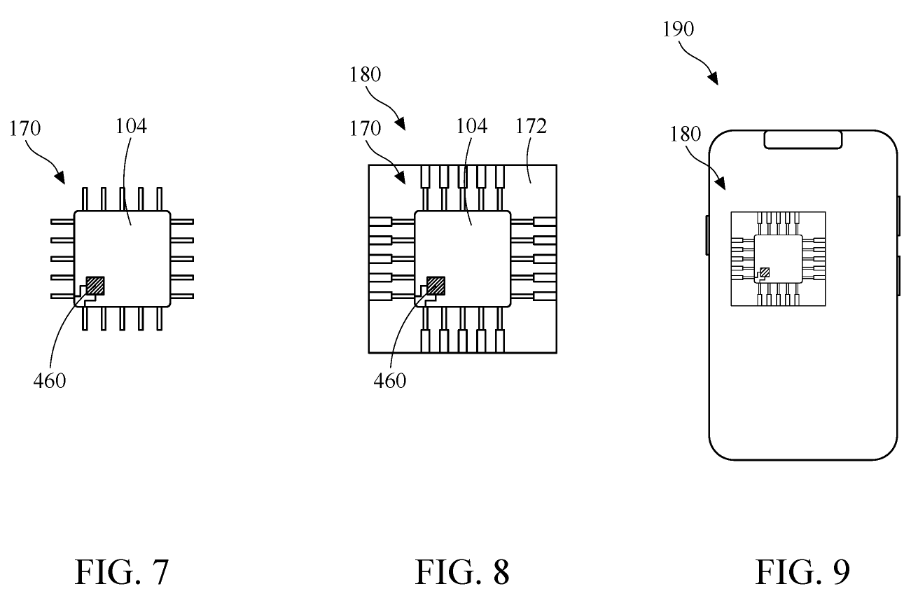

FIG. 5 is a flow chart of a method 1500 for measuring the antenna-effect ESD quantity in accordance with some embodiments of the disclosure. FIG. 7 is a schematic top view of a package 170 including the chip 104 divided from the semiconductor wafer 100 of FIG. 6. FIG. 8 is a schematic top view of a package 180 including the chip 104 of FIG. 7. FIG. 9 is a schematic top view of a final product 190 including the package 180 of FIG. 8.

The method 1500 includes steps 1502, 1504, 1506, 1508, 1510, 1512, 1514, 1516, 1518, and 1520. In step 1502, the chips 104 are fabricated on the semiconductor wafer 100, wherein each of the chips 104 includes the system 600 including the antenna effect electrostatic discharge (ESD) detection circuit 500A or 500B (or called a plasma induced charging monitoring circuit) for the internal circuit 400 (FIGS. 1 and 2). In some embodiments, the chips 104 are fabricated using a wafer-level process. In some embodiments, the drain of the antenna-effect ESD detection device 460 is connected to an antenna structure (e.g., the conductive routing 260D).

During the fabrication of the chips 104, the test devices 160 are formed in the scribe lines 102 surrounding the chips 104 on the semiconductor wafer 100. In some embodiments, the test device 160 and the antenna-effect ESD detection device 460 have the same structure. That is to say, the test devices 160 may serve as an antenna-effect ESD detection device 160. In some embodiments, the drain of each of the antenna-effect ESD detection devices 160 and 460 is connected to an antenna structure (e.g., the conductive routing 260D).

During step 1502, the initial threshold voltage of the antenna-effect ESD detection device 160 is measured. In some embodiments, the initial threshold voltage of the antenna-effect ESD detection device 160 in the scribe lines 102 (FIG. 6) of the semiconductor wafer 100 is measured after forming a bottom interconnection-level conductive trace (e.g., 1st interconnection-level conductive trace (M1)) on the chips 104. Alternatively, the initial threshold voltage of the antenna-effect ESD detection device 160 may be measured after forming upper interconnection-level conductive traces (e.g., 2nd interconnection-level conductive trace (M2) to the top interconnection-level conductive trace (Mtop)) located above the bottom interconnection-level conductive trace. In some embodiments, the initial threshold voltage of the antenna-effect ESD detection devices 160 located in the scribe lines 102 is substantially the same as that of antenna-effect ESD detection devices 460 located in the chips 104. Therefore, the initial threshold voltage of the antenna-effect ESD detection devices 460 located in the chips 104 may be obtained by measuring the initial threshold voltage of the antenna-effect ESD detection device 160 located in the scribe lines 102.

After measuring the initial threshold voltage of the antenna-effect ESD detection device 160, a plasma process is performed, and the antenna structure is exposed to the plasma process. In some embodiments, the plasma process includes a deposition process (e.g., plasma-enhanced chemical vapor deposition (PECVD)), an etching process (e.g., reactive-ion etching process) or an ashing process (e.g., plasma ashing) or other applicable plasma processes of forming an upper interconnection-level conductive trace above the bottom interconnection-level conductive trace on the chips 104.

In step 1504, after performing the plasma process, a first threshold voltage of the antenna-effect ESD detection device 460 is obtained by measuring a threshold voltage of the antenna-effect ESD detection device 160. Next, the threshold voltage shift between the initial threshold voltage and the first threshold voltage of the antenna-effect ESD detection device 460 (or the antenna-effect ESD detection device 160) is calculated. The threshold voltage shift of the antenna-effect ESD detection device 460 (or the antenna-effect ESD detection device 160) may reflect the charge quantity of the monitored plasma processes.

In step 1506, after calculating the threshold voltage shift between the initial threshold voltage and the first threshold voltage, charges trapped in the floating gate (e.g., the gate electrode 214 or the floating gate 314) of the antenna-effect ESD detection device 460 are removed. The threshold voltage of the antenna-effect ESD detection device 460 may be back to the initial threshold voltage. In some embodiments, the charges trapped in the floating gate of the antenna-effect ESD detection device 460 are moved by thermal erasing, electrical erasing or UV erasing.

In step 1508, a bumping process is performed on the chips 104 of the semiconductor wafer 100 to form bumps (not shown) on the chips 104. In some embodiments, the bumping process may include the plasma processes such as a deposition process (e.g., plasma-enhanced chemical vapor deposition (PECVD)), an etching process (e.g., reactive-ion etching process) or an ashing process (e.g., plasma ashing), a reflow process, a cleaning process (e.g., plasma cleaning process) or other applicable plasma processes. After performing the bumping process, a singulation process may be performed to dice the semiconductor wafer 100 into individual (singulated) chips 104 having bumps.

In step 1510, after performing the bumping process, a second threshold voltage of the antenna-effect ESD detection device 460 of the chip 104 (FIG. 6) in the package 170 measured. Next, the threshold voltage shift between the initial threshold voltage and the second threshold voltage is calculated. The threshold voltage shift may reflect the charge quantity of any plasma processes monitored during the bumping process.

In step 1512, after calculating the threshold voltage shift between the initial threshold voltage and the second threshold voltage, charges trapped in the floating gate (e.g., the gate electrode 214 or the floating gate 314) of the antenna-effect ESD detection device 460 are removed. The threshold voltage of the antenna-effect ESD detection device 460 may be back to the initial threshold voltage.

Alternatively, in step 1508, an assembly process may be performed to assemble the individual (singulated) chip 104 into a package 170 as shown in FIG. 7 after performing the dicing process. In some embodiments, the assembling process may include the plasma processes such as an etching process (e.g., reactive-ion etching process), a cleaning process (e.g., plasma cleaning process) or other applicable plasma processes.

In step 1510, after performing the assembly process, a third threshold voltage of the antenna-effect ESD detection device 460 of the chips 104 (FIG. 6) in the package 170 is measured. Next, the threshold voltage shift between the initial threshold voltage and the third threshold voltage is calculated. The threshold voltage shift may reflect the charge quantity of any plasma processes monitored during the bumping process and the assembly process.

In step 1512, after calculating the threshold voltage shift between the initial threshold voltage and the third threshold voltage, charges trapped in the floating gate (e.g., the gate electrode 214 or the floating gate 314) of the antenna-effect ESD detection device 460 in the package 170 are removed. The threshold voltage of the antenna-effect ESD detection device 460 in the package 170 may be back to the initial threshold voltage.

In step 1514, a chip on board (chip module) process may be performed to mount the package 170 on a base 172 (e.g., a substrate or a printed circuit board) to form a package assembly 180 as shown in FIG. 8. In some embodiments, the chip on board process may include the plasma processes such as an etching process (e.g., reactive-ion etching process), a cleaning process (e.g., plasma cleaning process), a treatment process (e.g., plasma treatment process) or other applicable plasma processes.

In step 1516, after performing the chip on board (chip module) process, a fourth threshold voltage of the antenna-effect ESD detection device 460 of the chip 104 (FIG. 6) in the package 170 of the package assembly 180 is measured. Next, the threshold voltage shift between the initial threshold voltage and the fourth threshold voltage is calculated. The threshold voltage shift may reflect the charge quantity of the plasma processes monitored during the chip on board (chip module) process.

In step 1518, after calculating the threshold voltage shift between the initial threshold voltage and the fourth threshold voltage, charges trapped in the floating gate (e.g., the gate electrode 214 or the floating gate 314) of the antenna-effect ESD detection device 460 in the package assembly 180 are removed. The threshold voltage of the antenna-effect ESD detection device 460 in the package assembly 180 may be back to the initial threshold voltage.

In step 1520, subsequent processes may be performed to build the package assembly 180 and other assemblies into a final product (e.g., a cell phone) as shown in FIG. 9.

The method 1500 for measuring the antenna-effect ESD quantity may help to monitor the charge quantity of plasma processes performed during the fabrication from the chip to the final product. For example, during the fabrication of the chips 104, the threshold voltage shift of the antenna-effect ESD detection device 460 (or the antenna-effect ESD detection device 160) may reflect the charge quantity of the monitored plasma processes. The threshold voltage shift of the antenna-effect ESD detection device 460 may reflect the charge quantity of the plasma processes monitored during the bumping process, the assembly process, and the chip on board (chip module) process.

Embodiments provide an antenna effect electrostatic discharge (ESD) detection circuit. The antenna effect ESD detection circuit includes a first antenna-effect ESD detection device and a first external electrostatic discharge (ESD) protection device. The first antenna-effect ESD detection device is coupled between a first pad and a second pad. The first external electrostatic discharge (ESD) protection device is coupled between an I/O pad and the first pad. The internal circuit is coupled to the I/O pad, the first external ESD protection device, and the first antenna-effect ESD detection device.

In some embodiments, the first pad receives a power supply voltage, and the second pad is coupled to a ground terminal.

In some embodiments, the first antenna-effect ESD detection device comprises a single one-time programmable (OTP) memory detection device or a single flash memory device.

In some embodiments, when the first external ESD protection device is a diode, the anode of the first external ESD protection device is coupled to the I/O pad and the cathode of the first external ESD protection device is coupled to the first pad.

In some embodiments, the drain of the first antenna-effect ESD detection device is connected to an antenna structure.

In some embodiments, the antenna structure is a drain conductive routing.

In some embodiments, the first antenna-effect ESD detection device and the first external ESD protection device are connected in parallel.

In some embodiments, the first antenna-effect ESD detection device is coupled between the first pad and the I/O pad.

In some embodiments, the antenna effect ESD detection circuit further includes a second external electrostatic discharge (ESD) protection device coupled between the I/O pad and the second pad. The internal circuit is coupled to the second external ESD protection device.

In some embodiments, when the second external ESD protection device is a diode, the anode of the second external ESD protection device is coupled to the second pad and the cathode of the first external ESD protection device is coupled to the I/O pad.

In some embodiments, the antenna effect ESD detection circuit further includes a second antenna-effect ESD detection device coupled between the first pad and the second pad. The second antenna-effect ESD detection device and the second external ESD protection device are connected in parallel.

In some embodiments, the second antenna-effect ESD detection device is coupled between the I/O pad and the second pad.

In some embodiments, when an electrostatic discharge event caused by antenna effect occurs at the first pad, a first threshold voltage of the first antenna-effect ESD detection device is higher than the initial threshold voltage of the first antenna-effect ESD detection device measured before the electrostatic discharge event caused by antenna effect occurs.

Embodiments also provide a method for measuring the antenna-effect ESD quantity. The method includes fabricating a chip surrounded by a scribe line on a semiconductor wafer. The chip includes an antenna effect electrostatic discharge (ESD) detection circuit for an internal circuit. The antenna effect ESD detection circuit includes an antenna-effect ESD detection device and an external electrostatic discharge (ESD) protection device. The antenna-effect ESD detection device is coupled between the first pad and the second pad. The external electrostatic discharge (ESD) protection device is coupled between an I/O pad and the first pad. The internal circuit is coupled to the I/O pad, the external ESD protection device, and the antenna-effect ESD detection device. The drain of the antenna-effect ESD detection device is connected to a first antenna structure. The method further includes obtaining a first threshold voltage of the antenna-effect ESD detection device of the chip. The method further includes removing charges trapped in a floating gate of the antenna-effect ESD detection device.

In some embodiments, the method for measuring the antenna-effect ESD quantity further includes fabricating a second antenna-effect ESD detection device in the scribe line during the fabricating of the chip, wherein the first and second antenna-effect ESD detection devices have the same structure, and the drain of the second antenna-effect ESD detection devices is connected to a second antenna structure. The method further includes obtaining the initial threshold voltage of the antenna-effect ESD detection device during the fabricating of the chip. The initial threshold voltage of the antenna-effect ESD detection device is obtained by measuring an initial threshold voltage of the second antenna-effect ESD detection device. The method further includes exposing the first antenna structure to a plasma process. The method further includes calculating the threshold voltage shift between the initial threshold voltage and the first threshold voltage. The first threshold voltage of the antenna-effect ESD detection device is obtained by measuring a first threshold voltage of the second antenna-effect ESD detection device.

In some embodiments, the initial threshold voltage of the antenna-effect ESD detection device is obtained after forming a bottom interconnection-level conductive trace on the chips.

In some embodiments, the plasma process comprises a deposition process, an etching process or an ashing process of forming an upper interconnection-level conductive trace above the bottom interconnection-level conductive trace on the chips.

In some embodiments, the method for measuring the antenna-effect ESD quantity further includes performing a bumping process on the chip of the semiconductor wafer. The method further includes measuring a second threshold voltage of the antenna-effect ESD detection device. The method further includes removing charges trapped in the floating gate of the antenna-effect ESD detection device.

In some embodiments, the method for measuring the antenna-effect ESD quantity further includes assembling the chip into a package. The method further includes measuring a third threshold voltage of the antenna-effect ESD detection device. The method further includes removing charges trapped in the floating gate of the antenna-effect ESD detection device.

In some embodiments, the method for measuring the antenna-effect ESD quantity further includes mounting the package on a base. The method further includes measuring a fourth threshold voltage of the antenna-effect ESD detection device of the chip in the package. The method further includes removing charges trapped in the floating gate of the antenna-effect ESD detection device of the chip in the package.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. An antenna-effect electrostatic discharge (ESD) detection circuit, comprising:
a first antenna-effect ESD detection device coupled between a first pad and a second pad; and
a first external electrostatic discharge (ESD) protection device coupled between an input/output (I/O) pad and the first pad,
wherein the internal circuit is coupled to the I/O pad, the first external ESD protection device, and the first antenna-effect ESD detection device.

2. The antenna-effect ESD detection circuit as claimed in claim 1, wherein the first pad receives a power supply voltage, and the second pad is coupled to ground.

3. The antenna-effect ESD detection circuit as claimed in claim 1, wherein the first antenna-effect ESD detection device comprises a one-time programmable (OTP) memory detection device or a flash memory device.

4. The antenna-effect ESD detection circuit as claimed in claim 1, wherein when the first external ESD protection device is a diode, an anode of the first external ESD protection device is coupled to the I/O pad and a cathode of the first external ESD protection device is coupled to the first pad.

5. The antenna-effect ESD detection circuit as claimed in claim 1, wherein a drain of the first antenna-effect ESD detection device is connected to an antenna structure.

6. The antenna-effect ESD detection circuit as claimed in claim 5, wherein the antenna structure is a drain conductive routing.

7. The antenna-effect ESD detection circuit as claimed in claim 1, wherein the first antenna-effect ESD detection device and the first external ESD protection device are connected in parallel.

8. The antenna-effect ESD detection circuit as claimed in claim 7, wherein the first antenna-effect ESD detection device is coupled between the first pad and the I/O pad.

9. The antenna-effect ESD detection circuit as claimed in claim 1, further comprising:
a second external electrostatic discharge (ESD) protection device coupled between the I/O pad and the second pad, wherein the internal circuit is coupled to the second external ESD protection device.

10. The antenna-effect ESD detection circuit as claimed in claim 9, wherein when the second external ESD protection device is a diode, an anode of the second external ESD protection device is coupled to the second pad and a cathode of the second external ESD protection device is coupled to the I/O pad.

11. The antenna-effect ESD detection circuit as claimed in claim 9, further comprising:
a second antenna-effect ESD detection device coupled between the first pad and the second pad, wherein the second antenna-effect ESD detection device and the second external ESD protection device are connected in parallel.

12. The antenna-effect ESD detection circuit as claimed in claim 10, wherein the second antenna-effect ESD detection device is coupled between the I/O pad and the second pad.

13. The antenna-effect ESD detection circuit as claimed in claim 1, wherein when an antenna-effect ESD event occurs at the first pad, a first threshold voltage of the first antenna-effect ESD detection device is higher than an initial threshold voltage of the first antenna-effect ESD detection device measured before the antenna-effect ESD event occurs.

14. A method for measuring antenna-effect effect electrostatic discharge (ESD) quantity, comprising:
fabricating a chip surrounded by a scribe line on a semiconductor wafer, wherein the chip comprises an antenna-effect ESD detection circuit for an internal circuit, wherein the antenna-effect ESD detection circuit comprises:
an antenna-effect ESD detection device coupled between a first pad and a second pad; and
an external ESD protection device coupled between an I/O pad and the first pad,
wherein the internal circuit is coupled to the I/O pad, the external ESD protection device, and the antenna-effect ESD detection device, and a drain of the antenna-effect ESD detection device is connected to an antenna structure;
obtaining a first threshold voltage of the antenna-effect ESD detection device of the chip; and
removing charges trapped in a floating gate of the antenna-effect ESD detection device.

15. The method for measuring antenna-effect ESD quantity as claimed in claim 14, further comprising:
fabricating a second antenna-effect ESD detection device in the scribe line during the fabricating of the chip, wherein the first and second antenna-effect ESD detection devices have the same structure, and a drain of the second antenna-effect ESD detection device is connected to a second antenna structure;
obtaining an initial threshold voltage of the antenna-effect ESD detection device during the fabricating of the chip, wherein the initial threshold voltage of the antenna-effect ESD detection device is obtained by measuring an initial threshold voltage of the second antenna-effect ESD detection device;
exposing the antenna structure to a plasma process; and
calculating a threshold voltage shift between the initial threshold voltage and the first threshold voltage, wherein the first threshold voltage of the antenna-effect ESD detection device is obtained by measuring a first threshold voltage of the second antenna-effect ESD detection device.

16. The method for measuring antenna-effect ESD quantity as claimed in claim 14, wherein the initial threshold voltage of the antenna-effect ESD detection device is obtained after forming a bottom interconnection-level conductive trace on the chips.

17. The method for measuring antenna-effect ESD quantity as claimed in claim 14, wherein the plasma process comprises a deposition process, an etching process or an ashing process of forming an upper interconnection-level conductive trace above the bottom interconnection-level conductive trace on the chips.

18. The method for measuring antenna-effect ESD quantity as claimed in claim 14, further comprising:
performing a bumping process on the chip of the semiconductor wafer;
measuring a second threshold voltage of the antenna-effect ESD detection device; and
removing charges trapped in the floating gate of the antenna-effect ESD detection device.

19. The method for measuring antenna-effect ESD quantity as claimed in claim 14, further comprising:
assembling the chip into a package;
measuring a third threshold voltage of the antenna-effect ESD detection device; and
removing charges trapped in the floating gate of the antenna-effect ESD detection device.

20. The method for measuring antenna-effect ESD quantity as claimed in claim 19, further comprising:
mounting the package on a base;
measuring a fourth threshold voltage of the antenna-effect ESD detection device of the chip in the package; and
removing charges trapped in the floating gate of the antenna-effect ESD detection device of the chip in the package.
